(19) United States
(12) Patent Application Publication
(10) Pub. No.: US 2013/0249566 A1
(43) Pub. Date: Sep. 26, 2013

(54) Kelvin Sense Probe Calibration

(71) Applicant: James Huntington, Beaverton, OR (US)

(72) Inventor: James Huntington, Beaverton, OR (US)

(73) Assignee: ELECTRO SCIENTIFIC INDUSTRIES, INC., Portland, OR (US)

(21) Appl. No.: 13/428,959

(22) Filed: Mar. 23, 2012

(51) Int. Cl. G01R 35/00

(52) U.S. Cl. 324/601

(57) ABSTRACT

Calibrating automatic test systems for testing electronic components using Kelvin probes is taught. A nominal contact resistance of a Kelvin probe is measured using a test slug to replace an electronic component to be measured on the test system. The measured resistance is stored by the test system and can be used to compensate for a measured value for an electronic component. A test slug can be periodically inserted into the test system to update the contact resistance measure and/or track the contact resistance to measure Kelvin probe wear and/or contamination.

### TECHNICAL FIELD

This disclosure relates in general to testing electronic components using an automated test system.

### BACKGROUND

Electronic devices of all types, including computing devices, consumer products, telecommunications equipment and automotive electronics, for example, contain electronic components that can be passive or active components. Active electronic components include integrated circuits, multichip packages and semiconductor devices such as transistors and light emitting diodes (LEDs), for example. Passive electronic components include capacitors, resistors, inductors and packages containing multiple components such as multi-layer ceramic capacitors (MLCCs), for example. Both active and passive components require testing before being assembled into electronic devices. Testing can be performed both to insure reliability of the electronic components and to sort the electronic components into groups having similar electronic characteristics. An electronic component being tested is sometimes referred to as a device under test (DUT), and these terms and the term component are used interchangeably herein.

### BRIEF SUMMARY

Disclosed embodiments include methods, apparatuses and systems for calibrating electronic component test systems having a plurality of component carriers. One method includes inserting a first test slug into a first component carrier of the plurality of component carriers and moving the first component carrier with the first test slug into a test position. The first test plug is probed with a Kelvin test probe and a first probe resistance is measured. The method also includes storing a nominal probe resistance set to the first probe resistance, inserting an electronic component in a second component carrier of the plurality of component carriers and moving the second component carrier with the electronic component into the test position. The electronic component is probed with the Kelvin test probe, and an electrical properties of the electronic component is measured using the Kelvin test probe to obtain a measured value.

Another aspect of the teachings herein is an apparatus for calibrating an electronic component test system. The apparatus comprises a Kelvin probe, a test station having test electronics, a plurality of component carriers mounted for movement to the test station, the plurality of component carriers including at least a first component carrier and a second component carrier, at least a first test slug, a memory, and a processor configured to execute instructions stored in the memory. The processor can cause the electronic component test system to move the first component carrier holding the first test slug to the test station, probe the first test slug with the Kelvin probe, measure a first probe resistance using the test electronics and the first test slug, store a nominal probe resistance set to the first probe resistance, move the second component carrier holding an electronic component to the test station, probe the electronic component with the Kelvin test probe, and measure an electrical property of the electronic component at the test station using the Kelvin test probe to obtain a measured value.

Variations of these embodiments and other embodiments are described hereinafter. For example, in various embodiments, the measured value can be compensated by the nominal probe value and/or the nominal probe value can be updated by processing another test slug.

### BRIEF DESCRIPTION OF THE DRAWINGS

FIG. 1 is a block diagram showing an example of an electronic component test system according to disclosed embodiments;

FIG. 2 is a schematic diagram of Kelvin probes according to disclosed embodiments; and

FIG. 3 is a diagram of a DUT and Kelvin probes according to disclosed embodiments;

FIG. 4 is a diagram of a test slug and Kelvin probes according to disclosed embodiments;

FIG. 5 is a flowchart of Kelvin probe calibration according to disclosed embodiments; and

FIG. 6 is a flowchart of Kelvin probe updating according to disclosed embodiments.

### DETAILED DESCRIPTION

Reliability testing for electronic components can include applying test signals to the components and comparing measured results against predetermined values to decide if the component is good or bad. Sorting electronic components can include applying test signals to the components and using the measured results to determine the performance qualities of the component and thereby determine how the component will be rated and marketed, for example. Both types of testing can use equipment in the form of test systems to handle large volumes of components at high speed without damaging the components while producing accurate test results over long periods of time relative to the amount of time required for testing a single component. For example, testing a single electronic component can take less than one second, while the test system can be expected to run continuously for many hours. As used herein the term signal refers to any electrical or electronic voltage, current, waveform, data, information or electromagnetic radiation supplied or received in any form, including wired or wireless.

Both reliability testing and sorting can be performed by probing, which means temporarily applying one or more conductive test leads to conductive areas on the electronic component, sometimes called “pads,” and applying an electronic test signal to the electronic component. The system can then measure electrical properties of the electronic component in response to the test signal. Electrical properties measured with test probes, for example, can include measuring the resistance of the component, which can involve applying a known voltage and measuring the current flowing through the component. Capacitance, for example, can be measured by applying a known voltage and measuring the rate at which current flows into the device. A measurement can also be made in cooperation with other equipment, for example when testing LEDs, a known voltage and current can be applied to the LED and the light output measured by a photometric device.

The accuracy of electrical properties measured by a test system can depend upon the accuracy with which the voltage or other signal applied to the component is known. For measurement involving small differences in voltages, for example, the test probe resistance can be a significant part of the total resistance measured. A Kelvin test probe can reduce the effect that test probe resistance has on the measurement, sometimes called parasitic resistance, by applying two probes in close proximity to a single pad. The first probe, called the force probe, carries the test voltage and current to or from the device while the second probe, called the sense probe, measures the applied voltage. In this way the voltage drop across the probes carrying the test current can be minimized, since the sense probe can be part of a much higher impedance circuit that carries less current and therefore suffers less voltage drop. Using Kelvin probes can result in more accurate test results with higher resolution and sensitivity than non-Kelvin probes.

According to the teachings herein, measuring Kelvin probe resistance during operation of a test system can permit changes in test values to be tracked over time by monitoring possibly changing parasitic resistance. The resistance can desirably be used for contact verification, probe wear characterization and/or compensation of measured values for a DUT.

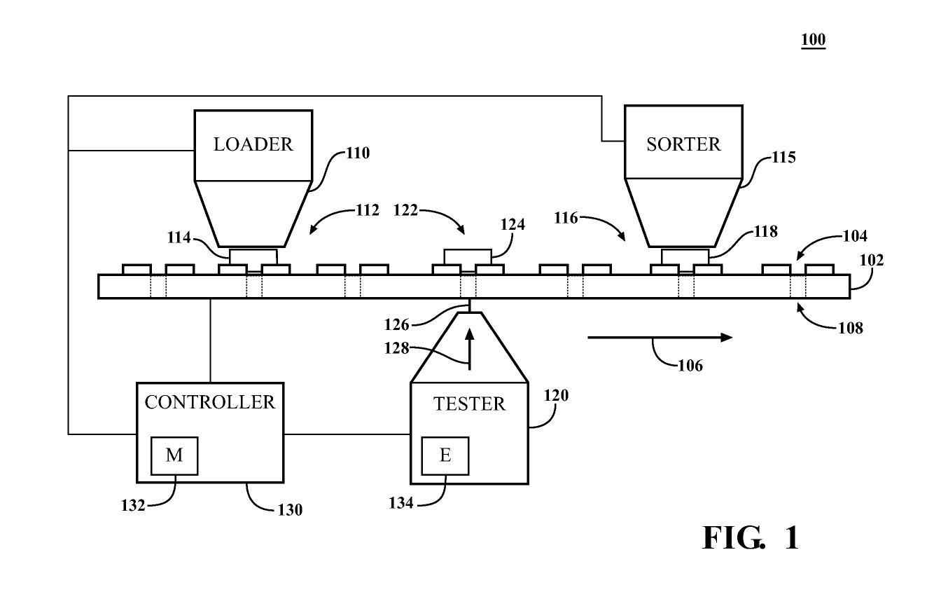

FIG. 1 is a block diagram of an example electronic component test system 100 according to disclosed embodiments. An example of an electronic component test system that can be adapted to accomplish disclosed embodiments include the ESI Model 3800 manufactured by Electro Scientific Industries, Inc., Portland OR. Electronic component test system 100 includes a track 102 having a plurality of component carriers 104 operating under control of a controller 130. Track 102 can be arranged as a disk, belt, or any other means of maintaining recirculating or reciprocating motion wherein electronic components can be loaded, tested and unloaded using track 102 or component carriers 104 attached to track 102. Component carriers 104 can be attached or applied to the track 102 and are operative to receive one or more electronic components 114, 118, 124, for example, temporarily hold components 114, 118, 124 in a pose that permits testing and permits components 114, 118, 124 to be unloaded while being indexed by track 102.

Component carriers 104 can be indexed in the direction of arrow 106 from a load station 112, to a test station 122 and to a sort station 116 in an intermittent or continuous fashion under control of controller 130. Controller 130 can be a computing device having a memory 132. The term “computing device” includes any device or multiple devices capable of processing information including without limitation: servers, hand-held devices, laptop computers, desktop computers, special purpose computers, and general purpose computers programmed to perform the techniques described herein. Memory 34 can be read only memory (ROM), random access memory (RAM) or any other suitable memory device or combination of devices capable of storing data, including disk drives or removable media such as a CF card, SD card or the like. In one implementation, controller 130 includes a central processing unit (CPU) that performs in accordance with a software program stored in memory 132 to perform the functions described herein. In another implementation, controller 130 includes hardware, such as application-specific integrated circuits (ASICs), microcontrollers or field-programmable gate arrays (FPGAs), programmed to perform some or all of the functions described herein.

As shown in FIG. 1, test system 100 under control of controller 130 loads electronic components at load station 112 with loader 110, indexes components to test station 122 and unloads components at sort station 116 using sorter 115. Indexing refers to a type of start/stop motion wherein track 102 can be stopped to hold component carriers 104 momentarily still at load station 112, test station 122 or sort station 116 to permit loading, testing or unloading and then can be re-started to move component carriers 104 positions at load station 112, test station 122 or sort station 116, where track 102 is again momentarily stopped to permit loading, testing or unloading and then re-started. The indexing movement between stations can optionally be performed in a series of smaller steps. Indexing proceeds continuously at to permit numbers of components to be loaded, tested and unloaded/sorted efficiently and at high speed. Continuous movement is possible in some test systems. At load station 112, a loader 110 has, for example, a bulk load of electronic components to be individually loaded on to a component carrier 104. Track 102 is indexed to position an empty component carrier 104 proximate to loader 110 at load station 112. Loader 110, under control of controller 130, loads an electronic component 114 into component carrier 104 at load station 112. Track 102 indexes a component carrier 104 with a loaded electronic component 124 to test station 122 under control of controller 130. At test position 122, a tester 120 can test component 124 by probing with Kelvin probes 126 under control of controller 130. In this example, probing is accomplished by moving one or more Kelvin probes 126 in the direction of arrow 128 through an opening 108 in track 102 and component carrier 104 to contact component 124.

Tester 120 contains test electronics 134 that can send signals though Kelvin probes 126 to component 124 and can receive signals from component 124 through Kelvin probes 126 to measure electrical properties of component 124. An example of test electronics 134 is the ESI Model 820 source/measurement unit, manufactured by Electro Scientific Industries, Inc., Portland, OR. The measured electrical properties and other signals generated by additional testing, for example photometric data from electro-optical components, can be sent to controller 130 for further processing or storage in memory 132. Following testing, tester 120 can retract Kelvin probes 126 to permit track 102 to index the next electronic component to be tested to test station 122.

At sort station 116, an electronic component 118 can be unloaded from a component carrier 104 using a sorter 115. Sorter 115 can remove component 118 using, for example, compressed air, vacuum or mechanical means. Sorter 115 can include one or more bins and one or more channels or tubes for conveying component 118 to one of the bins under control of controller 130 depending upon the results of testing of component 118. Sorting by sorter 115 can include simple “go/no go” sorting where electronic components that have measured electrical properties indicating that they have failed testing are separated from electronic components that have passed testing based on their measured electrical properties. More elaborate sorting schemes where the measured electrical properties of electronic components are separated into multiple bins depending upon values of the measured electrical properties are also possible.

Note that although this description describes loading, testing and unloading one component resting in each component carrier 104, it can be desirable for multiple components to be loaded into each component carrier 104 for subsequent testing and unloading to speed processing. In this case, tester 120 could include a plurality of Kelvin probes 126. When referring to a Kelvin probe 126 and a measurement of the probe resistance herein, more than one Kelvin probe 126 and more than one corresponding measurement is not excluded.

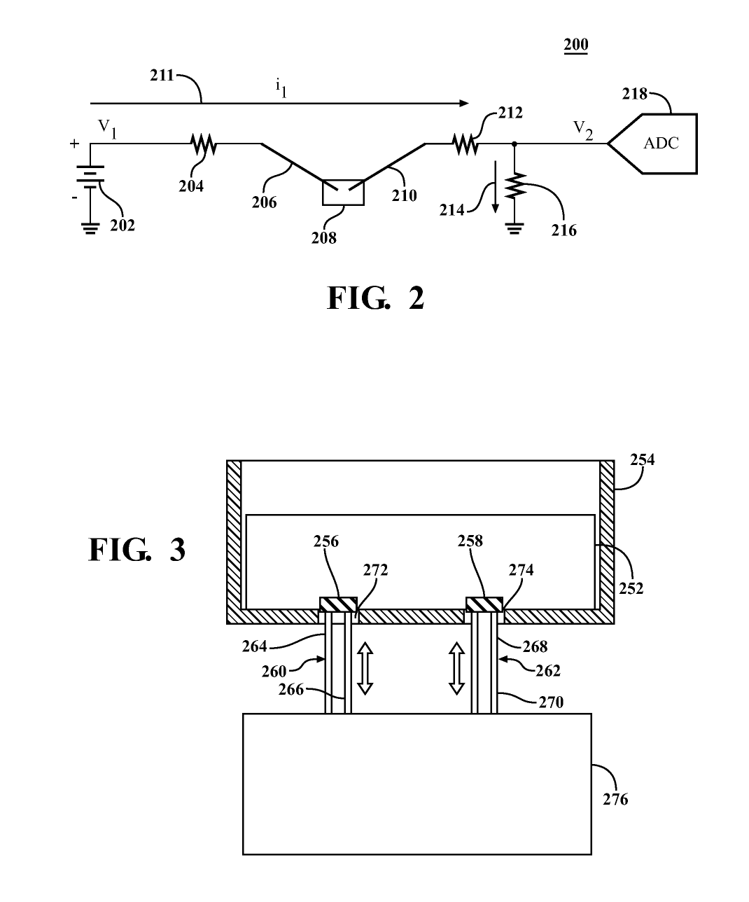

Disclosed embodiments can calibrate and track Kelvin probes 126 by replacing component 124 with a test slug and measuring Kelvin probe resistance with tester 120 and storing the measured Kelvin probe resistance in memory 132. FIG. 2 is a diagram showing a Kelvin probe circuit 200 applied to a test slug 208 to measure probe resistance values. A Kelvin probe circuit 200 can include two probes, a force probe 206 to supply the electrical signal to test slug 208 and a sense probe 210 to acquire the electrical signal as it is applied to test slug 208. Since the sense circuitry to which the sense probe is attached can be a high impedance circuit while the force circuitry to which force probe 206 is attached can be a lower impedance circuit to deliver the current required to test slug 208, the cumulative effects of the resistances of the sense circuit due to circuitry internal to the test electronics, cabling, connectors and probes can be lower for sense probe 210 than the force circuitry to which force probe 206 is attached, thereby improving the accuracy and sensitivity of measurements performed using sense probe 210.

Kelvin probe circuit 200 as shown has a voltage source 202 that supplies voltage v₁, which causes current i₁ to flow through Kelvin probe circuit 200 in the direction of an arrow 211. While voltage source 202 is represented by a battery symbol and hence represents a DC source, any circuit operative to supply a signal that permits testing of test slug 208 can be used. Resistor 204 represents the combined resistance of the force circuit, which can include printed circuit board (PCB) trace resistance, PCB component resistance, connector resistances, cable resistances and the resistance of force probe 206 (collectively, “parasitic resistance”). Current i₁ flows through force probe 206 to the point where it contacts test slug 208, and then flows through test slug 208 to the point where sense probe 210 contacts test slug 208. Test slug 208 can be made of very low resistance materials, for example a solid piece of copper. Other configurations of test slug 208 are possible, as long as test slug 208 appears as a low or substantially zero resistance to the test electronics and matches the size, shape and weight of an electronic component closely enough to be able to be held and tested using component carrier 104. Resistor 212 represents the combined resistance of the sense circuit, which can include PCB resistances, PCB components resistances, connector resistances, cable resistances and the resistance of sense probe 210. Resistor 216 can have a low resistance, for example 22 Ohms, to permit the majority of current i₁ to flow to ground in the direction of an arrow 214, since the input at an analog-to-digital converter (ADC) 218 can have a relatively high impedance. ADC 218 can measure voltage v₂, which indicates the voltage drop caused by resistors 204 and 212, and thereby determine the probe resistance values of Kelvin probe circuit 200. Although not shown, a buffer may optionally be coupled to the input of ADC 218.

Once the combined probe resistance values of the Kelvin probes, called nominal contact resistance, is known, any increase in the combined resistance is representative of Kelvin probe wear, since typically only the probe resistance values of resistors 204 and 212 change over time. The nominal contact resistance or nominal resistance Rₙₒₘᵢₙₐₗ can be calculated by the formula:

Rₙₒₘᵢₙₐₗ=(V₁−V₂)/i₁ (1)

Measuring the contact resistance R_{contact} at points in time after nominal resistance Rₙₒₘᵢₙₐₗ is measured can permit an increase from nominal resistance Rₙₒₘᵢₙₐₗ to be calculated by the formula:

R_{contact}=[v₁−v₂−(Rₙₒₘᵢₙₐₗ*i₁)]/i₁ (2)

Knowing nominal resistance Rₙₒₘᵢₙₐₗ and contact resistance R_{contact} of Kelvin probe circuit 200 can permit electronic component test system 100 (such as through the use of controller 130) to compensate for the Kelvin probe resistance and thereby improve the accuracy and sensitivity of DUT measurements. By comparing the measured nominal contact resistance of newly installed Kelvin probes to subsequent contact resistance measures using equation (2), wear on the Kelvin probes can be estimated and tracked, permitting, for example, the Kelvin probes to be replaced, cleaned or otherwise serviced in a timely fashion.

FIG. 3 shows a DUT 252 in a component carrier 254 being probed by Kelvin probes 260, 262 according to disclosed embodiments. A first contact 256 on DUT 252 can be probed by Kelvin probe 260, which includes force probe 264 and sense probe 266, and a second contact 258 can be probed by Kelvin probe 262, which includes force probe 268 and sense probe 270. Kelvin probes 260, 262 can be moved up and down in the directions indicated by the arrows in order to, for example, move up to probe DUT 252 through holes 272, 274 provided in component carrier 254 and then move down to permit component carrier 254 holding DUT 252 to index to a next position. A tester 276 includes test electronics that supply and receive signals from Kelvin probes 260, 262 to measure electrical properties of DUT 252. The up and down motion of Kelvin probes 260, 262 can be accomplished mechanically, for example through mechanical linkages that detect component carrier 254 being indexed into position, or electrically, for example through solenoids or voice coils operating in response to detecting component carrier 254 being indexed into position, or a combination of both.

In operation, testing an electronic component or DUT 252 can employ two Kelvin probes 260, 262, each having a respective force probe 264, 268 and sense probe 266, 270 to send and receive signals to DUT 252, where one Kelvin probe 260 can be used to supply a signal to DUT 252 and one Kelvin probe 262 is used to receive a signal indicating the measurements. Other configurations can use a Kelvin probe 262 to supply the signal and a conventional probe to receive the signal.

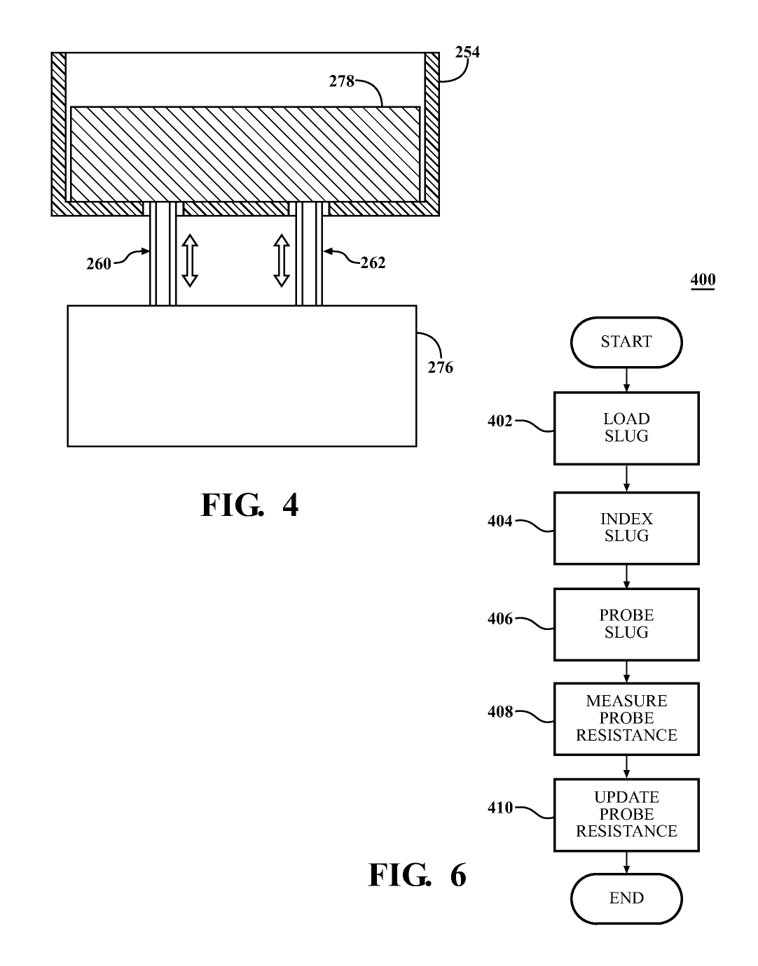

FIG. 4 shows a test slug 278 held in component carrier 254 being probed by Kelvin proves 260, 262 while supplying and receiving test signals from test electronics included in tester 276. Note that test slug 278 replaces DUT 252 in component carrier 254 and can be probed by Kelvin probes 260, 262 without modification to tester 276, Kelvin probes 260, 262 or component carrier 254. Test slug 278 presents a low or substantially zero resistance to signals from tester 276.

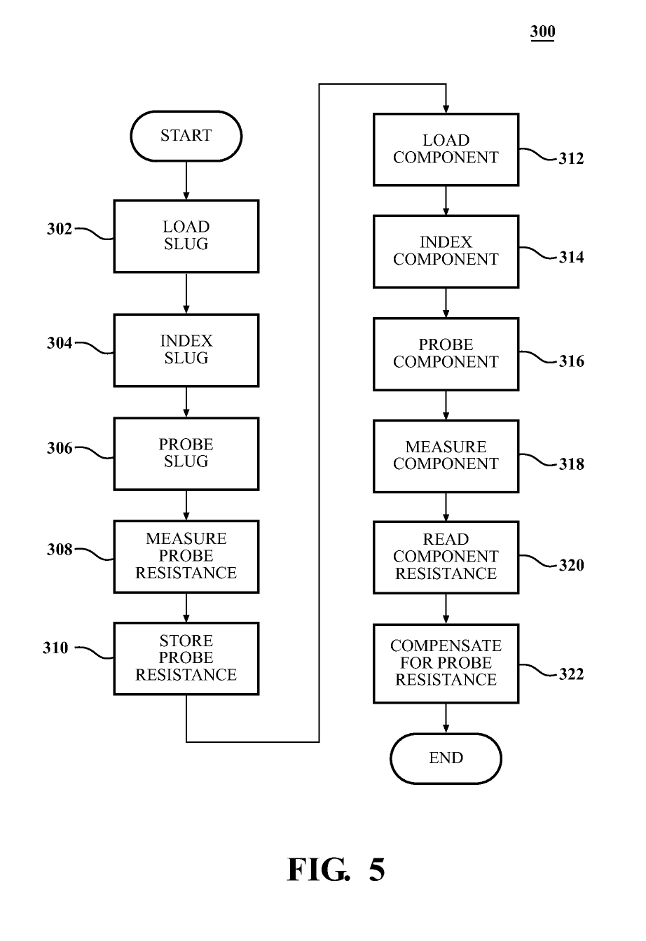

FIG. 5 is a flowchart showing a method of operation 300 for measuring an electronic component with Kelvin probes using an electronic component test system according to disclosed embodiments. Using test system 100 as an example structure to implement steps of method of operation 300, a test slug 208 can be loaded into a component carrier 104 at step 302 using loader 110 of load station 112. At step 304, the loaded test slug 208 can be indexed along track 102 into position at test station 122. At step 306, the test slug is probed using Kelvin probes 126, and the nominal contact resistance of test slug 208 is measured according to, for example, equation (1) in step 308. At step 310, the measured nominal contact resistance is stored, for example at memory 132. At step 312, an electronic component is loaded into a component carrier 104 at load station 112. Then, component carrier 104 and its supported DUT are indexed into position at test station 122 at step 314. At step 316, the DUT is probed using Kelvin probes 126, and a resistance value of the DUT is measured at step 318. At step 320, the stored probe nominal resistance is read from memory 132, for example, and the measured resistance of the DUT is adjusted or compensated for the resistance of Kelvin probes 126 at step 322. This could involve, for example, subtracting Rₙₒₘᵢₙₐₗ from the measured resistance value for the DUT. Other compensation techniques are possible. Method of operation 300 continues performing steps 312 through 322 for a number of cycles corresponding to a set of components, generally but not necessarily decided by a user. For example, the set could conform to testing of a single tested component type. As another example, the set could conform to a known performance of the Kelvin probes, such as an average number of cycles to breakdown. In yet another example, the set could form a predetermined number of components based on a defined maintenance protocol.

During the processing of steps 314 through 322, such as between one set of electronic components and the next, the Kelvin probe resistance can be updated. FIG. 6 is a flowchart showing a method of operation 400 for updating the nominal contact resistance of Kelvin probes using an electronic component test system according to disclosed embodiments. Again using test system 100 as an example structure, method of operation 400 starts at step 402, where test slug 208 is inserted into a component carrier 104 at load station 112. At step 404, component carrier 104 and test slug 208 are indexed to test station 122. At step 406, test slug 208 is probed, while its Kelvin probe resistance is measured at step 408. At step 410, the nominal contact resistance measure stored in memory 132 is updated to reflect the new resistance measure R_{contact} using equation (2), for example, or controller 130 can indicate that the contact resistance has deviated from acceptable levels. The updated nominal contact resistance can then be used for resistance compensation for the next set of components in step 322 of FIG. 5, for example.

The sensitivity of Kelvin probes can permit probe contact verification, where the test system verifies whether or not a probe is actually making contact with the DUT by comparing the output with the Kelvin probe nominal resistance, for example. Measuring Kelvin probe resistance during operation of a test system, such as periodically, can permit changes in test values to be tracked over time by monitoring possibly changing parasitic resistance. This permits probe wear characterization, which can determine how probes are performing and tracks wear over time by measuring probe resistance when contact is made with a DUT. The tracked test values can be used to monitor the expected wear or contamination of Kelvin probe tips to, for example, permit replacement of tips before the wear or contamination is significant enough to present erroneous test results or detect anomalous wear or contamination conditions.

Tracking test values can also be used to dynamically adjust test values, wherein compensation by the probe contact resistance can improve the accuracy of the measurement of the DUT. In another example, the tracked test values can be logged for storage by the test system to permit statistical analysis of the performance of the test system, such as test system 100.

Measuring and tracking Kelvin probe resistance can require calibration. As described herein, calibrating a test system using Kelvin probes can include applying the Kelvin probes to a calibration device that has an accurately known resistance and performing a measurement. One type of calibration device is the described test slug, which can be a metallic object, sometimes copper, in the shape of an electronic component that can be assumed to have, for testing purposes, low or substantially zero resistance. Any resistance measured by the test system as a result of testing the test slug can be attributed to the test system itself, including the Kelvin probes. This resistance can be stored by the test system and can be used to compensate and track this resistance when making measurements of DUTs and be used to compensate for the Kelvin probe resistance, thereby making the measurements more accurate and sensitive.

Another issue with testing electronic components using Kelvin probes can be maintaining calibration. Electronic test systems can be in use for long periods of time testing many electronic components. As Kelvin probes are used, the resistance of the probes can change, for example due to buildup of material transferred to the tip of the Kelvin probes from the pads of the DUTs. This change in contact resistance can cause the measurements made using the Kelvin probes to change or drift over time and eventually require the Kelvin probes to be replaced. Calibrating Kelvin probes periodically during the testing period as described herein can improve the accuracy of the measurements and thereby improve the accuracy and sensitivity of the testing.

Employing a test slug according to disclosed embodiments can permit calibration of test equipment in clean room environments. Calibrating test equipment in clean room environments can be difficult if the calibration requires additional test equipment to be brought into the clean room. Test slugs are inexpensive and small, therefore test slugs representing the types of components to be tested on the test system can be qualified for clean room use at the same time the test system is installed and kept with the test system in the clean room. Therefore, there is no requirement for additional equipment to perform testing during the testing period.

Some electronic components can be combined with other components in to electronic assemblies before testing. For example, electronic components can be attached to substrates or interposer devices so that the contacts cannot be accessed directly. In these cases a test slug can be attached to the substrate or interposer device in the same way as the component, thereby permitting calibration of the test system in the same configuration as the component will be in during testing.

Disclosed embodiments can permit calibration of electronic component test system while requiring minimal changes to the test equipment by employing a test slug. A test slug is defined as an article manufactured to mimic the size, shape and weight of a DUT while providing substantially zero ohm resistance to the test system. In this way, a test slug can be substituted for a DUT in a test system without requiring any changes in the operation of the test system. The test slug is designed to provide a low or substantially zero ohm resistance when probed by the test system using Kelvin probes in the same manner and at the same position as the contact pads of the DUT.

While this disclosure includes certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method for calibrating an electronic component test system including a plurality of component carriers, the method comprising:
A) inserting a first test slug into a first component carrier of the plurality of component carriers;
B) moving the first component carrier with the first test slug into a test position;
C) probing the first test slug with a Kelvin test probe;
D) measuring a first probe resistance of the Kelvin test probe;
E) storing a nominal probe resistance set to the first probe resistance;
F) inserting an electronic component into a second component carrier of the plurality of component carriers;
G) moving the second component carrier with the electronic component into the test position;
H) probing the electronic component with the Kelvin test probe; and
I) measuring an electrical property of the electronic component using the Kelvin test probe to obtain a measured value.

2. The method of claim 1 wherein the measuring the electrical property includes compensating the measured value by the nominal probe resistance.

3. The method of claim 1, further comprising:
storing the first probe resistance.

4. The method of claim 1, further comprising:
inserting a second test slug into a third component carrier of the plurality of component carriers after performing steps F) through I) for a plurality of electronic components;
moving the third component carrier with the second test slug into the test position;
probing the second test slug with the Kelvin test probe; and
measuring a second probe resistance of the Kelvin test probe.

5. The method of claim 4, further comprising:
replacing the Kelvin test probe when the second probe resistance varies from the nominal probe resistance by a predetermined amount.

6. The method of claim 4, further comprising:
updating the nominal probe resistance based on a comparison between the first probe resistance and the second probe resistance.

7. The method of claim 1, further comprising:
inserting a second test slug into a third component carrier of the plurality of component carriers after performing steps F) through I) for a plurality of electronic components;
moving the third component carrier with the second test slug into the test position;
probing the second test slug with the Kelvin test probe;
measuring a second probe resistance of the Kelvin test probe; and
updating the nominal probe resistance based on a comparison between the first probe resistance and the second probe resistance.

8. The method of claim 1 wherein the electronic component is one of a passive electronic component or an active electronic component.

9. The method of claim 8 wherein the passive electronic component is one of a resistor, a capacitor or an inductor.

10. The method of claim 8 wherein the active electronic component is one of a light-emitting diode, a semiconductor device or an integrated circuit.

11. The method of claim 1 wherein the first test slug has a size and shape corresponding to the electronic component and provides a low resistance in response to being probed by the Kelvin test probe.

12. The method of claim 11 wherein the first test slug includes copper.

13. An apparatus for calibrating an electronic component test system, comprising:
a Kelvin probe;
a test station having test electronics;
a plurality of component carriers mounted for movement to the test station, the plurality of component carriers including at least a first component carrier and a second component carrier;
at least a first test slug;
a memory; and
a processor configured to execute instructions stored in the memory to:
A) move the first component carrier holding the first test slug to the test station;
B) probe the first test slug with the Kelvin probe;
C) measure a first probe resistance using the test electronics and the first test slug;
D) store a nominal probe resistance set to the first probe resistance;
E) move the second component carrier holding an electronic component to the test station;
F) probe the electronic component with the Kelvin test probe; and
G) measure an electrical property of the electronic component at the test station using the Kelvin test probe to obtain a measured value.

14. The apparatus of claim 13 wherein the processor is configured to compensate the measured value using the nominal probe resistance.

15. The apparatus of claim 13 wherein the processor is configured to:
load the first test slug into the first component carrier; and subsequently
load the electronic component into the second component carrier.

16. The apparatus of claim 13 wherein the processor is configured to:
insert the first test slug or a second test slug into a third component carrier of the plurality of component carriers after E), F) and G) are performed for a first plurality of electronic components;
move the third component carrier into the test station;
probe the first test slug or the second test slug with the Kelvin test probe;
measure a second probe resistance of the Kelvin test probe; and
update the nominal probe resistance using the second probe resistance when the second probe resistance is different from the first probe resistance.

17. The apparatus of claim 16 wherein the processor is configured to:
store the second probe resistance.

18. The apparatus of claim 16 wherein the processor is configured to:
perform E), F) and G) for a second plurality of electronic components after updating the nominal probe resistance.

19. The apparatus of claim 13 wherein the test slug has a size and shape corresponding to the electronic component and provides a low resistance in response to being probed by the Kelvin test probe.

20. The apparatus of claim 13 wherein the test slug includes copper.
